(19) United States
(12) Patent Application Publication
(10) Pub. No.: US 2011/0171774 A1
(43) Pub. Date: Jul. 14, 2011

(54) CLEANING OPTIMIZATION OF PECVD SOLAR FILMS

(75) Inventors: Francimar C. Schmitt, Santa Clara, CA (US); Zheng Yuan, Cupertino, CA (US); Yi Zheng, Sunnyvale, CA (US); Fan Yang, Sunnyvale, CA (US); Lipan Li, Foster City, CA (US)

(73) Assignee: APPLIED MATERIALS, INC., Santa Clara, CA (US)

(21) Appl. No.: 12/967,648

(22) Filed: Dec. 14, 2010

Related U.S. Application Data
(60) Provisional application No. 61/288,730, filed on Dec. 21, 2009.

(51) Int. Cl. H01L 31/0376

(52) U.S. Cl. 438/73; 438/96; 257/E31.047

(57) ABSTRACT

Embodiments of the present invention generally provide a method for forming a plurality of thin film single or multi-junction solar cell in a substrate processing chamber. In one embodiment, a method for processing a plurality of thin film solar cell substrates includes depositing sequentially a first undoped layer and a first doped layer over a surface of a first substrate and a chamber component in a single processing chamber, removing the substrate having the doped and undoped layers from the processing chamber, removing the second doped layer deposited on the chamber component to expose underlying first undoped layer which serves as a seasoning layer for a second substrate to be processed in the processing chamber, and depositing sequentially a second undoped layer and a second doped layer on the second substrate in the processing chamber. In one example, the first undoped layer is amorphous silicon or microcrystalline silicon. A full cleaning process may be performed at desired intervals to expose the surfaces of the chamber component before a regular seasoning process and the subsequent depositions are proceeded in the processing chamber.

### CROSS-REFERENCE TO RELATED APPLICATIONS

This application claims benefit of U.S. provisional patent application Ser. No. 61/288,730, filed Dec. 21, 2009, which is incorporated by reference herein.

### BACKGROUND OF THE INVENTION

1. Field of the Invention

Embodiments of the present invention generally relate to the fabrication of silicon solar cells. More particularly, the present invention relates to improved cleaning methods for processing thin film single or multi-junction solar cell in a processing chamber.

2. Description of the Related Art

Solar cells are photovoltaic (PV) devices that convert sunlight directly into electrical power. Solar cells typically have one or more p-n junctions. Each junction comprises two different regions within a semiconductor material where one side is denoted as the p-type region and the other as the n-type region. When the p-n junction of a solar cell is exposed to sunlight (consisting of energy from photons), the sunlight is directly converted to electricity through the PV effect. Solar cells generate a specific amount of electric power and are tiled into modules sized to deliver the desired amount of system power. Solar modules are joined into panels with specific frames and connectors.

Plasma enhanced chemical vapor deposition (PECVD) chambers for the deposition of semiconductor materials on substrates is well known in the art. Plasma processes include supplying a process gas mixture to a vacuum chamber and then applying electromagnetic energy to excite the process gas to a plasma state. The plasma decomposes the gas mixture into ion species that perform the desired deposition on an appropriate substrate. The silicon solar cells formed by such deposition processes on an appropriate substrate include layers of amorphous silicon as well as micro-crystalline silicon. These layers form the p-i-n devices which absorb solar radiation and as a result, generate electrical current.

In performing the desired deposition to form the p-i-n structures, it is important that contamination of the i-layers does not occur during the i-layer formation process from prior deposited p-type or n-type deposited layers that may be formed in the same or subsequent processing chambers in a processing sequence. Phosphorous contamination in the i-layer of the device can affect or reduce cell conversion efficiency performance of the device. Typically, i-n layers deposition is done in-situ, i.e., i-layer film is deposited followed by n-layer film in the same chamber. Once the deposition is completed, the substrate is moved out of the chamber and chamber hardware cleaning is performed, followed by an amorphous silicon seasoning process to coat the chamber components in preparation for the next substrate to be deposited with i-n films. Although this cleaning manner maintains the quality of film deposition, it severely reduces the throughput performance of the system.

Therefore, there is a need for an improved method of processing thin film single or multi-junction solar cell in a substrate processing chamber to improve the throughput performance while maintaining good film deposition quality.

### SUMMARY OF THE INVENTION

Embodiments of the present invention generally provide a method for forming a plurality of thin film single or multi-junction solar cell in a substrate processing chamber. In one embodiment, a method for processing a plurality of thin film solar cell substrates includes depositing sequentially a first undoped layer and a first doped layer over a surface of a first substrate and a chamber component in a single processing chamber, removing the substrate having the doped and undoped layers from the processing chamber, removing the second doped layer deposited on the chamber component to expose underlying first undoped layer which serves as a seasoning layer for a second substrate to be processed in the processing chamber, and depositing sequentially a second undoped layer and a second doped layer on the second substrate in the processing chamber. In one example, the first undoped layer is amorphous silicon or microcrystalline silicon. A full cleaning process may be performed at desired intervals to expose the surfaces of the chamber component before a regular seasoning process and the subsequent depositions are proceeded in the processing chamber.

In another embodiment, a method of processing a plurality of thin film solar cell substrates includes depositing a first intrinsic type layer on a surface of a first substrate and on a chamber component in the first processing chamber, depositing a first doped layer over the first intrinsic type layer formed on the first substrate and on the chamber component in the first processing chamber, removing the first substrate having the first doped layer and the first intrinsic type layer from the first processing chamber, and performing a first partial cleaning process in the first processing chamber, wherein the first partial cleaning process removes substantially the first doped layer that was deposited on the chamber component during the first doped layer deposition while leaving the first intrinsic type layer of the chamber component.

In yet another embodiment, a method of processing a plurality of thin film solar cell substrates, includes depositing sequentially a first intrinsic type layer and a first doped layer on a surface of a first substrate and on a first chamber component in a first processing chamber, wherein the first chamber component and the first substrate are disposed in a processing region of the first processing chamber when the first intrinsic type layer and the first doped layer are deposited on the first substrate, removing the substrate having the first intrinsic type layer and the first doped layer from the first processing chamber, performing a partial cleaning process in the first processing chamber to remove the first doped layer that was deposited over the first intrinsic type layer on the first chamber component during the first doped layer deposition, thereby exposing underlying first intrinsic type layer which serves as a seasoning layer for a second substrate to be processed in the first processing chamber, and depositing sequentially a second intrinsic type layer and a second doped layer on a surface of the second substrate and on the first chamber component in the first processing chamber, wherein the first chamber component and the second substrate are disposed in the processing region of the first processing chamber when the second intrinsic type layer and the second doped layer are deposited on the second substrate. The method may further comprise depositing an underlying doped layer on the first substrate in a second processing chamber before depositing the first intrinsic type layer on the first substrate, wherein the underlying doped layer comprises dopant atoms that are not the same as dopant atoms disposed in the first doped layer, such as a p-type silicon containing layer or an n-type silicon containing layer. In one aspect, a full cleaning process may be performed at desired intervals to expose the surfaces of the chamber component before a regular seasoning process and the subsequent depositions are proceeded in the processing chamber. The seasoning process is provided to deposit a seasoning layer comprises amorphous silicon or microcrystalline silicon.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic diagram of certain embodiments of a multi-junction solar cell oriented toward the light or solar radiation.

FIG. 2 is a schematic diagram of the multi-junction solar cell of FIG. 1 further including an n-type amorphous silicon buffer layer.

FIG. 3 is a schematic diagram of the multi-junction solar cell of FIG. 1 further including a p-type microcrystalline silicon contact layer.

FIG. 4 is a schematic cross-section view of one embodiment of a plasma enhanced chemical vapor deposition (PECVD) chamber in which one or more films of a solar cell may be deposited.

FIG. 5 is a top schematic view of one embodiment of a process system having a plurality of process chambers.

FIG. 6 illustrates one embodiment of a processing sequence performed in a processing chamber in which a series of deposition process steps are performed on multiple substrates with a partial cleaning process being performed after each of the deposition process step prior to a full cleaning process and a seasoning process is performed.

### DETAILED DESCRIPTION

Embodiments of the present invention include improved methods for forming thin film multi-junction solar cells. In one embodiment, the method generally includes depositing sequentially first an intrinsic type silicon-containing layer and second an n-doped silicon-containing layer over a surface of the substrate in a single processing chamber. After the completion of i-n layer deposition in the processing chamber, the deposited substrate is removed and a partial cleaning process is performed in the processing chamber. The partial cleaning process is short (e.g., about 5-30 seconds) so as to remove only or substantially the n-doped layer that was deposited on the chamber components during the n-layer film deposition. The purpose of the short partial cleaning process is to eliminate the unwanted dopant from the phosphorous film (i.e., n-doped layer) present on the chamber components and expose the underlying intrinsic type layer to serve as a seasoning layer for the next substrate to be processed in the processing chamber for i-n layer deposition. By performing the above-mentioned partial cleaning process, it is possible to run multiple substrates (followed by partial cleans) through the chamber before a full clean and seasoning becomes necessary, thereby significantly increasing throughput performance of the current PECVD processes.

### Exemplary Multi-Junction Solar Cells

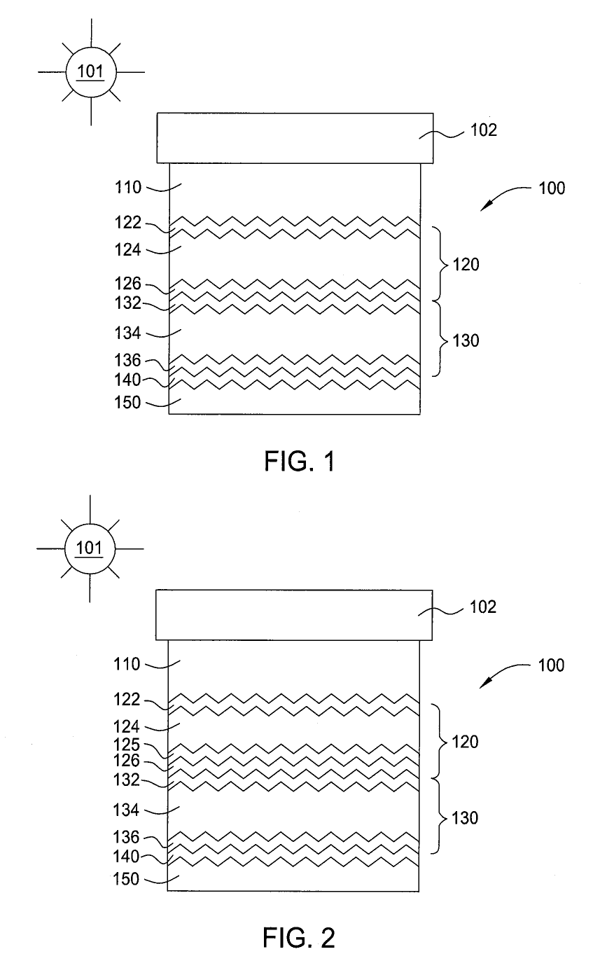

FIG. 1 is a schematic diagram of certain embodiments of a multi-junction solar cell 100 oriented toward the light or solar radiation 101. Solar cell 100 includes a substrate 102, which includes but not limited to a glass substrate, polymer substrate, metal substrate, or other suitable substrate, with thin films formed thereover. The solar cell 100 may further include a first transparent conducting oxide (TCO) layer 110 formed over the substrate 102, a first p-i-n junction 120 formed over the first TCO layer 110, a second p-i-n junction 130 formed over the first p-i-n junction 120, a second TCO layer 140 formed over the second p-i-n junction 130, and a metal back layer 150 formed over the second TCO layer 140. To improve light absorption by reducing light reflection, the substrate and/or one or more of thin films formed thereover may be optionally textured by wet, plasma, ion, and/or mechanical processes. For example, in the embodiment shown in FIG. 1, the first TCO layer 110 is textured and the subsequent thin films deposited thereover will generally follow the topography of the surface below it.

The first TCO layer 110 and the second TCO layer 140 may each include tin oxide, zinc oxide, indium tin oxide, cadmium stannate, combinations thereof, or other suitable materials. It is understood that the TCO materials may also include additional dopants and components. For example, zinc oxide may further include dopants, such as aluminum, gallium, boron, and other suitable dopants. Zinc oxide preferably comprises 5 atomic % or less of dopants, and more preferably comprises 2.5 atomic % or less aluminum. In certain instances, the substrate 102 may be provided by the glass manufacturers with the first TCO layer 110 already provided.

The first p-i-n junction 120 may include a p-type amorphous silicon layer 122, an intrinsic type amorphous silicon layer 124 formed over the p-type amorphous silicon layer 122, and an n-type microcrystalline silicon layer 126 formed over the intrinsic type amorphous silicon layer 124. In certain embodiments, the p-type amorphous silicon layer 122 may be formed to a thickness between about 60 Å and about 300 Å. In certain embodiments, the intrinsic type amorphous silicon layer 124 may be formed to a thickness between about 1,500 Å and about 3,500 Å. In certain embodiments, the n-type microcrystalline silicon layer 126 may be formed to a thickness between about 100 Å and about 400 Å.

The second p-i-n junction 130 may include a p-type microcrystalline silicon layer 132, an intrinsic type microcrystalline silicon layer 134 formed over the p-type microcrystalline silicon layer 132, and an n-type amorphous silicon layer 136 formed over the intrinsic type microcrystalline silicon layer 134. In certain embodiments, the p-type microcrystalline silicon layer 132 may be formed to a thickness between about 100 Å and about 400 Å. In certain embodiments, the intrinsic type microcrystalline silicon layer 134 may be formed to a thickness between about 10,000 Å and about 30,000 Å. In certain embodiments, the n-type amorphous silicon layer 136 may be formed to a thickness between about 100 Å and about 500 Å.

The metal back layer 150 may include, but not limited to a material selected from the group consisting of Al, Ag, Ti, Cr, Au, Cu, Pt, alloys thereof, or combinations thereof. Other processes may be performed to form the solar cell 100, such a laser scribing processes. Other films, materials, substrates, and/or packaging may be provided over metal back layer 150 to complete the solar cell. The solar cells may be interconnected to form modules, which in turn can be connected to form arrays.

Solar radiation 101 is absorbed by the intrinsic layers of the p-i-n junctions 120, 130 and is converted to electron-holes pairs. The electric field created between the p-type layer and the n-type layer that stretches across the intrinsic layer causes electrons to flow toward the n-type layers and holes to flow toward the p-type layers creating current. The first p-i-n junction 120 includes an intrinsic type amorphous silicon layer 124 and the second p-i-n junction 130 includes an intrinsic type microcrystalline silicon layer 134 because amorphous silicon and microcrystalline silicon absorb different wavelengths of solar radiation 101. Therefore, the solar cell 100 is more efficient since it captures a larger portion of the solar radiation spectrum. The intrinsic layer of amorphous silicon and the intrinsic layer of microcrystalline are stacked in such a way that solar radiation 101 first strikes the intrinsic type amorphous silicon layer 124 and then strikes the intrinsic type microcrystalline silicon layer 134 since amorphous silicon has a larger bandgap than microcrystalline silicon. Solar radiation not absorbed by the first p-i-n junction 120 continues on to the second p-i-n junction 130. It was surprising to find that the thicknesses disclosed herein of the p-i-n layers of the first p-i-n junction 120 and the second p-i-n junction 130 provided for a solar cell with improved efficiency and with a reduced cost of producing the same. Not wishing to be bound by theory unless explicitly recited in the claims, it is believed that on one hand a thicker intrinsic layer 124, 134 is beneficial to absorb a greater amount of the solar radiation spectrum and that on the other hand if the intrinsic layer 124, 134 and/or the p-i-n junctions 120, 130 are too thick the flow of electrons therethrough would be hampered.

In one aspect, the solar cell 100 does not need to utilize a metal tunnel layer between the first p-i-n junction 120 and the second p-i-n junction 130. The n-type microcrystalline silicon layer 126 of the first p-i-n junction 120 and the p-type microcrystalline silicon layer 132 has sufficient conductivity to provide a tunnel junction to allow electrons to flow from the first p-i-n junction 120 to the second p-i-n junction 130.

In one aspect, it is believed that the n-type amorphous silicon layer 136 of the second p-i-n junction 130 provides increased cell efficiency since it is more resistant to attack from oxygen, such as the oxygen in air. Oxygen may attack the silicon films and thus forming impurities which lower the capability of the films to participate in electron/hole transport therethrough.

FIG. 2 is a schematic diagram of the multi-junction solar cell 100 of FIG. 1 further including an n-type amorphous silicon buffer layer 125 formed between the intrinsic type amorphous silicon layer 124 and the n-type microcrystalline silicon layer 126. In certain embodiments, the n-type amorphous silicon buffer layer 125 may be formed to a thickness between about 10 Å and about 200 Å. It is believed that the n-type amorphous silicon buffer layer 125 helps bridge the bandgap offset that is believed to exist between the intrinsic type amorphous silicon layer 124 and the n-type microcrystalline silicon layer 126. Thus it is believed that cell efficiency is improved due to enhanced current collection.

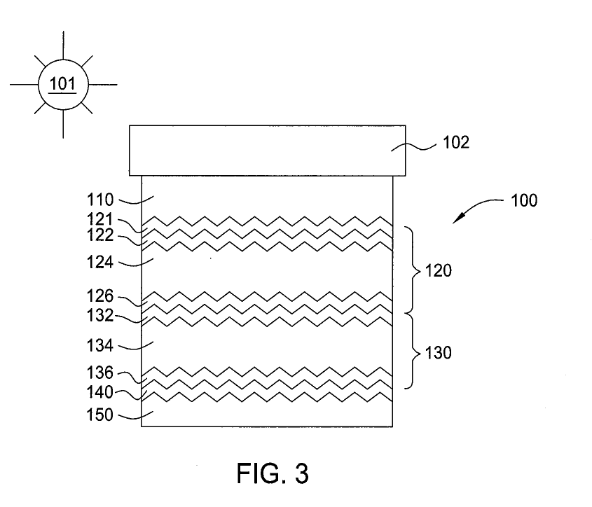

FIG. 3 is a schematic diagram of the multi-junction solar cell 100 of FIG. 1 further including a p-type microcrystalline silicon contact layer 121 formed between the first TCO layer 110 and the p-type amorphous silicon layer 122. In certain embodiments, the p-type microcrystalline silicon contact layer 121 may be formed to a thickness between about 60 Å and about 300 Å. It is believed that the p-type microcrystalline silicon contact layer 121 helps achieve low resistance contact with the TCO layer. Thus, it is believed that cell efficiency is improved since current flow between the p-type type amorphous silicon layer 122 and the zinc oxide first TCO layer 110 is improved. It is preferred that the p-type microcrystalline silicon contact layer 121 be used with a TCO layer including a material that is resistant to a hydrogen plasma, such as zinc oxide, since a large amount of hydrogen is used to form the contact layer. It has been found that tin oxide is not suitable to be used in conjunction with the p-type microcrystalline silicon contact layer since it is chemically reduced by the hydrogen plasma. It is further understood that the solar cell 100 may further include an optional n-type amorphous silicon buffer layer formed between the intrinsic type amorphous silicon layer 124 and the n-type microcrystalline silicon layer 126 as described in FIG. 2.

### Exemplary Hardware and Process

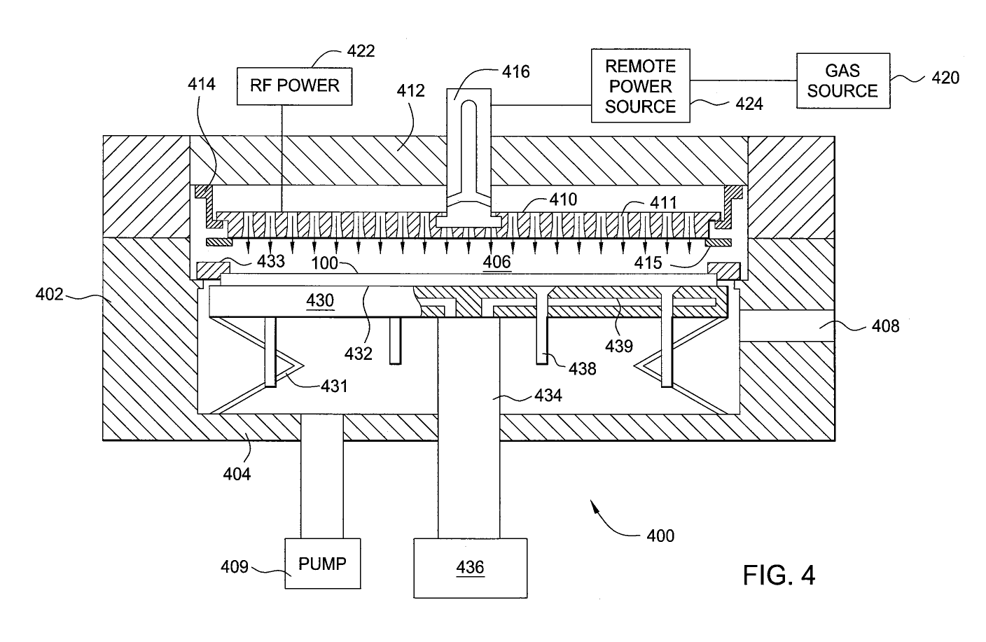

FIG. 4 is a schematic cross-section view of one embodiment of a plasma enhanced chemical vapor deposition (PECVD) chamber 400 in which one or more films of a solar cell, such as the solar cell 100 of FIG. 1, FIG. 2, or FIG. 3, may be deposited. One suitable plasma enhanced chemical vapor deposition chamber is available from Applied Materials, Inc., located in Santa Clara, Calif. It is contemplated that other deposition chambers, including those from other manufacturers, may be utilized to practice the present invention.

The chamber 400 generally includes walls 402, a bottom 404, and a showerhead 410 having a plurality of passage 411, and substrate support 430 which define a processing region 406. The process volume is accessed through a valve 408 such that the substrate, may be transferred in and out of the chamber 400. The substrate support 430 includes a substrate receiving surface 432 for supporting a substrate and stem 434 coupled to a lift system 436 to raise and lower the substrate support 430. A shadow from 433 may be optionally placed over periphery of the substrate. Lift pins 438 are moveably disposed through the substrate support 430 to move a substrate to and from the substrate receiving surface 432. The substrate support 430 may also include heating and/or cooling elements 439 to maintain the substrate support 430 at a desired temperature. The substrate support 430 may also include grounding straps 431 to provide RF grounding at the periphery of the substrate support 430. Examples of grounding straps are disclosed in U.S. Pat. No. 6,024,044 issued on Feb. 15, 2000 to Law et al. and U.S. patent application Ser. No. 11/613,934 filed on Dec. 20, 2006 to Park et al., which are both incorporated by reference in their entirety to the extent not inconsistent with the present disclosure.

The showerhead 410 is coupled to a backing plate 412 at its periphery by a suspension 414. The showerhead 410 may also be coupled to the backing plate by one or more center supports 416 to help prevent sag and/or control the straightness/curvature of the showerhead 410. A gas source 420 is coupled to the backing plate 412 to provide gas through the backing plate 412 and through the showerhead 410 to the substrate receiving surface 432. A vacuum pump 409 is coupled to the chamber 400 to control the processing region 406 at a desired pressure. An RF power source 422 is coupled to the backing plate 412 and/or to the showerhead 410 to provide a RF power to the showerhead 410 so that an electric field is created between the showerhead and the substrate support so that a plasma may be generated from the gases between the showerhead 410 and the substrate support 430. Various RF frequencies may be used, such as a frequency between about 0.3 MHz and about 200 MHz. In one embodiment the RF power source is provided at a frequency of 13.56 MHz. Examples of showerheads are disclosed in U.S. Pat. No. 6,477,980 issued on Nov. 12, 2002 to White et al., U.S. Publication 20050251990 published on Nov. 17, 2006 to Choi et al., and U.S. Publication 2006/0060138 published on Mar. 23, 2006 to Keller et al, which are all incorporated by reference in their entirety to the extent not inconsistent with the present disclosure.

A remote plasma source 424, such as an inductively coupled remote plasma source, may also be coupled between the gas source and the backing plate. Between processing substrates, a cleaning gas may be provided to the remote plasma source 424 so that a remote plasma is generated and provided to clean chamber components. The cleaning gas may be further excited by the RF power source 422 provided to the showerhead. Suitable cleaning gases include but are not limited to NF₃, F₂, and SF₆. Examples of remote plasma sources are disclosed in U.S. Pat. No. 5,788,778 issued Aug. 4, 1998 to Shang et al, which is incorporated by reference to the extent not inconsistent with the present disclosure.

The deposition methods for one or more silicon layers, such as one or more of the silicon layers of solar cell 100 of FIG. 1, FIG. 2, or FIG. 3, may include the following deposition parameters in the process chamber of FIG. 4 or other suitable chamber. A substrate having a surface area of 10,000 cm² or more, preferably 40,000 cm² or more, and more preferably 55,000 cm² or more is provided to the chamber. It is understood that after processing the substrate may be cut to form smaller solar cells.

In one embodiment, the heating and/or cooling elements 439 may be set to provide a substrate support temperature during deposition of about 400 degrees Celsius or less, preferably between about 100 degrees Celsius and about 400 degrees Celsius, more preferably between about 150 degrees Celsius and about 300 degrees Celsius, such as about 200 degrees Celsius.

The spacing during deposition between the top surface of a substrate disposed on the substrate receiving surface 432 and the showerhead 410 may be between 400 mil and about 1,200 mil, preferably between 400 mil and about 800 mil.

For deposition of silicon films, a silicon-based gas and a hydrogen-based gas are provided. Suitable silicon based gases include, but are not limited to silane (SiH₄), disilane (Si₂H₆), silicon tetrafluoride (SiF₄), silicon tetrachloride (SiCl₄), dichlorosilane (SiH₂Cl₂), and combinations thereof. Suitable hydrogen-based gases include, but are not limited to hydrogen gas (H₂). The p-type dopants of the p-type silicon layers may each include a group III element, such as boron or aluminum. Preferably, boron is used as the p-type dopant. Examples of boron-containing sources include trimethylboron (TMB (or B(CH₃)₃)), diborane (B₂H₆), BF₃, B(C₂H₅)₃, and similar compounds. Preferably, TMB is used as the p-type dopant. The n-type dopants of the n-type silicon layer may each include a group V element, such as phosphorus, arsenic, or antimony. Preferably, phosphorus is used as the n-type dopant. Examples of phosphorus-containing sources include phosphine and similar compounds. The dopants are typically provided with a carrier gas, such as hydrogen, argon, helium, and other suitable compounds. In the process regimes disclosed herein, a total flow rate of hydrogen gas is provided. Therefore, if a hydrogen gas is provided as the carrier gas, such as for the dopant, the carrier gas flow rate should be subtracted from the total flow rate of hydrogen to determine how much additional hydrogen gas should be provided to the chamber.

Certain embodiments of depositing a p-type microcrystalline silicon contact layer, such as contact layer 121 of FIG. 3, may include providing a gas mixture of hydrogen gas to silane gas in ratio of about 200:1 or greater. Silane gas may be provided at a flow rate between about 0.1 sccm/L and about 0.8 sccm/L. Hydrogen gas may be provided at a flow rate between about 60 sccm/L and about 500 sccm/L. Trimethylboron may be provided at a flow rate between about 0.0002 sccm/L and about 0.0016 sccm/L. In other words, if trimethylboron is provided in a 0.5% molar or volume concentration in a carrier gas, then the dopant/carrier gas mixture may be provided at a flow rate between about 0.04 sccm/L and about 0.32 sccm/L. The flow rates in the present disclosure are expressed as sccm per interior chamber volume. The interior chamber volume is defined as the volume of the interior of the chamber in which a gas can occupy. For example, the interior chamber volume of chamber 400 is the volume defined by the backing plate 412 and by the walls 402 and bottom 404 of the chamber minus the volume occupied therein by the showerhead assembly (i.e., including the showerhead 410, suspension 414, center support 415) and by the substrate support assembly (i.e., substrate support 430, grounding straps 431). An RF power between about 50 milliWatts/cm² and about 700 milliWatts/cm² may be provided to the showerhead. The RF powers in the present disclosure are expressed as Watts supplied to an electrode per substrate area. For example, for a RF power of 10,385 Watts supplied to a showerhead to process a substrate having dimensions of 220 cm×260 cm, the RF power would be 10,385 Watts/(220 cm×260 cm)=180 milliWatts/cm². The pressure of the chamber may be maintained between about 1 Torr and about 100 Torr, preferably between about 3 Torr and about 20 Torr, more preferably between 4 Torr and about 12 Torr. The deposition rate of the p-type microcrystalline silicon contact layer may be about 10 Å/min or more. The p-type microcrystalline silicon contact layer has a crystalline fraction between about 20 percent and about 80 percent, preferably between 50 percent and about 70 percent.

Certain embodiments of depositing a p-type amorphous silicon layer, such as the silicon layer 122 of FIG. 1, FIG. 2, or FIG. 3, may include providing a gas mixture of hydrogen gas to silane gas in a ratio of about 20:1 or less. Silane gas may be provided at a flow rate between about 1 sccm/L and about 10 sccm/L. Hydrogen gas may be provided at a flow rate between about 5 sccm/L and 60 sccm/L. Trimethylboron may be provided at a flow rate between about 0.005 sccm/L and about 0.05 sccm/L. In other words, if trimethylboron is provided in a 0.5% molar or volume concentration in a carrier gas, then the dopant/carrier gas mixture may be provided at a flow rate between about 1 sccm/L and about 10 sccm/L. Methane may be provided at a flow rate between about 1 sccm/L and 15 sccm/L. An RF power between about 15 milliWatts/cm² and about 200 milliWatts/cm² may be provided to the showerhead. The pressure of the chamber is maintained between about 0.1 Torr and 20 Torr, preferably between about 1 Torr and about 4 Torr. The deposition rate of the p-type amorphous silicon layer may be about 100 Å/min or more. Methane or other carbon containing compounds, such C₃H₈, C₄H₁₀, C₂H₂, can be used to improve the window properties (e.g. to lower absorption of solar radiation) of p-type amorphous silicon layer. Thus, an increased amount of solar radiation may be absorbed through the intrinsic layers and thus cell efficiency is improved.

Certain embodiments of depositing an intrinsic type amorphous silicon layer, such as the silicon layer 124 of FIG. 1, FIG. 2, or FIG. 3, include providing a gas mixture of hydrogen gas to silane gas in a ratio of about 20:1 or less. Silane gas may be provided at a flow rate between about 0.5 sccm/L and about 7 sccm/L. Hydrogen gas may be provided at a flow rate between about 5 sccm/L and 60 sccm/L. An RF power between 15 milliWatts/cm² and about 250 milliWatts/cm² may be provided to the showerhead. The pressure of the chamber may be maintained between about 0.1 Torr and 20 Torr, preferably between about 0.5 Torr and about 5 Torr. The deposition rate of the intrinsic type amorphous silicon layer may be about 100 Å/min or more.

Certain embodiments of depositing an n-type amorphous silicon buffer layer, such as the silicon layer 125 of FIG. 2, include providing hydrogen gas to silicon gas in a ratio of about 20:1 or less. Silane gas may be provided at a flow rate between about 1 sccm/L and about 10 sccm/L. Hydrogen gas may be provided at a flow rate between about 4 sccm/L and about 50 sccm/L. Phosphine may be provided at a flow rate between about 0.0005 sccm/L and about 0.0075 sccm/L. In other words, if phosphine is provided in a 0.5% molar or volume concentration in a carrier gas, then the dopant/carrier gas mixture may be provided at a flow rate between about 0.1 sccm/L and about 1.5 sccm/L. An RF power between about 15 milliWatts/cm² and about 250 milliWatts/cm² may be provided to the showerhead. The pressure of the chamber may be maintained between about 0.1 Torr and 20 Torr, preferably between about 0.5 Torr and about 4 Torr. The deposition rate of the n-type amorphous silicon buffer layer may be about 200 Å/min or more.

Certain embodiments of depositing a n-type microcrystalline silicon layer, such as the silicon layer 126 of FIG. 1, FIG. 2, or FIG. 3, may include providing a gas mixture of hydrogen gas to silane gas in a ratio of about 100:1 or more. Silane gas may be provided at a flow rate between about 0.1 sccm/L and about 0.8 sccm/L. Hydrogen gas may be provided at a flow rate between about 30 sccm/L and about 250 sccm/L. Phosphine may be provided at a flow rate between about 0.0005 sccm/L and about 0.004 sccm/L. In other words, if phosphine is provided in a 0.5% molar or volume concentration in a carrier gas, then the dopant/carrier gas may be provided at a flow rate between about 0.1 sccm/L and about 0.8 sccm/L. An RF power between about 100 milliWatts/cm² and about 900 milliWatts/cm² may be provided to the showerhead. The pressure of the chamber may be maintained between about 1 Torr and about 100 Torr, preferably between about 3 Torr and about 20 Torr, more preferably between 4 Torr and about 12 Torr. The deposition rate of the n-type microcrystalline silicon layer may be about 50 Å/min or more. The n-type microcrystalline silicon layer has a crystalline fraction between about 20 percent and about 80 percent, preferably between 50 percent and about 70 percent.

Certain embodiments of depositing a p-type microcrystalline silicon layer, such as silicon layer 132 of FIG. 1, FIG. 2, or FIG. 3, include providing a gas mixture of hydrogen gas to silane gas in a ratio of about 200:1 or greater. Silane gas may be provided at a flow rate between about 0.1 sccm/L and about 0.8 sccm/L. Hydrogen gas may be provided at a flow rate between about 60 sccm/L and about 500 sccm/L. Trimethylboron may be provided at a flow rate between about 0.0002 sccm/L and about 0.0016 sccm/L. In other words, if trimethylboron is provided in a 0.5% molar or volume concentration in a carrier gas, then the dopant/carrier gas mixture may be provided at a flow rate between about 0.04 sccm/L and about 0.32 sccm/L. An RF power between about 50 milliWatts/cm² and about 700 milliWatts/cm² may be provided to the showerhead. The pressure of the chamber may be maintained between about 1 Torr and about 100 Torr, preferably between about 3 Torr and about 20 Torr, more preferably between 4 Torr and about 12 Torr. The deposition rate of the p-type microcrystalline silicon layer may be about 10 Å/min or more. The p-type microcrystalline silicon contact layer has a crystalline fraction between about 20 percent and about 80 percent, preferably between 50 percent and about 70 percent.

Certain embodiments of depositing an intrinsic type microcrystalline silicon layer, such as silicon layer 134 of FIG. 1, FIG. 2, or FIG. 3, may include providing a gas mixture of silane gas to hydrogen gas in a ratio between 1:20 and 1:200. Silane gas may be provided at a flow rate between about 0.5 sccm/L and about 5 sccm/L. Hydrogen gas may be provided at a flow rate between about 40 sccm/L and about 400 sccm/L. In certain embodiments, the silane flow rate may be ramped up from a first flow rate to a second flow rate during deposition. In certain embodiments, the hydrogen flow rate may be ramped down from a first flow rate to a second flow rate during deposition. An RF power between about 300 milliWatts/cm² or greater, preferably 600 milliWatts/cm² or greater, may be provided to the showerhead. In certain embodiments, the power density may be ramped down from a first power density to a second power density during deposition. The pressure of the chamber is maintained between about 1 Torr and about 100 Torr, preferably between about 3 Torr and about 20 Torr, more preferably between about 4 Torr and about 12 Torr. The deposition rate of the intrinsic type microcrystalline silicon layer may be about 200 Å/min or more, preferably 500 Å/min. Methods and apparatus for deposited microcrystalline intrinsic layer are disclosed in U.S. patent application Ser. No. 11/426,127 filed Jun. 23, 2006, entitled “Methods and Apparatus for Depositing a Microcrystalline Silicon Film for Photovoltaic Device,” which is incorporated by reference in its entirety to the extent not inconsistent with the present disclosure. The microcrystalline silicon intrinsic layer has a crystalline fraction between about 20 percent and about 80 percent, preferably between 55 percent and about 75 percent. It was surprising to find that a microcrystalline silicon intrinsic layer having a crystalline fraction of about 70% or below provided an increase in open circuit voltage and leads to higher cell efficiency.

Certain embodiments of a method depositing a n-type amorphous silicon layer, such as the silicon layer 136 of FIG. 1, FIG. 2, or FIG. 3, may include depositing an optional first n-type amorphous silicon layer at a first silane flow rate and depositing a second n-type amorphous silicon layer over the first optional n-type amorphous silicon layer at a second silane flow rate lower than the first silane flow rate. The first optional n-type amorphous silicon layer may include providing a gas mixture of hydrogen gas to silane gas in a ratio of about 20:1 or less. Silane gas may be provided at a flow rate between about 1 sccm/L and about 10 sccm/L. Hydrogen gas may be provided at a flow rate between about 4 sccm/L and about 40 sccm/L. Phosphine may be provided at a flow rate between about 0.0005 sccm/L and about 0.0075 sccm/L. In other words, if phosphine is provided in a 0.5% molar or volume concentration in a carrier gas, then the dopant/carrier gas mixture may be provided at a flow rate between about 0.1 sccm/L and about 1.5 sccm/L. An RF power between 25 milliWatts/cm² and about 250 milliWatts/cm² may be provided to the showerhead. The pressure of the chamber may be maintained between about 0.1 Torr and about 20 Torr, preferably between about 0.5 Torr and about 4 Torr. The deposition rate of the first n-type type amorphous silicon layer may be about 200 Å/min or more. The second n-type amorphous silicon layer may include providing a gas mixture of hydrogen gas to silane gas in a ratio of about 20:1 or less. Silane gas may be provided at a flow rate between about 0.1 sccm/L and about 1 sccm/L. Hydrogen gas may be provided at a flow rate between about 1 sccm/L and about 10 sccm/L. Phosphine may be provided at a flow rate between 0.01 sccm/L and about 0.075 sccm/L. In other words, if phosphine is provided in a 0.5% molar or volume concentration in a carrier gas, then the dopant/carrier gas mixture may be provided at a flow rate between about 2 sccm/L and about 15 sccm/L. An RF power between 25 milliWatts/cm² and about 250 milliWatts/cm² may be provided to the showerhead. The pressure of the chamber may be maintained between about 0.1 Torr and about 20 Torr, preferably between about 0.5 Torr and about 4 Torr. The deposition rate of the second n-type type amorphous silicon layer may be about 100 Å/min or more. The second n-type amorphous silicon layer is heavily doped and has a resistivity of about 500 Ohm-cm or below. It is believed that the heavily n-type doped amorphous silicon provides improved ohmic contact with a TCO layer, such as second TCO layer 140. Thus, cell efficiency is improved. The optional first n-type amorphous silicon is used to increase the deposition rate for the entire n-type amorphous silicon layer. It is understood that the n-type amorphous silicon layer may be formed without the optional first n-type amorphous silicon and may be formed primarily of the heavily doped second n-type amorphous layer.

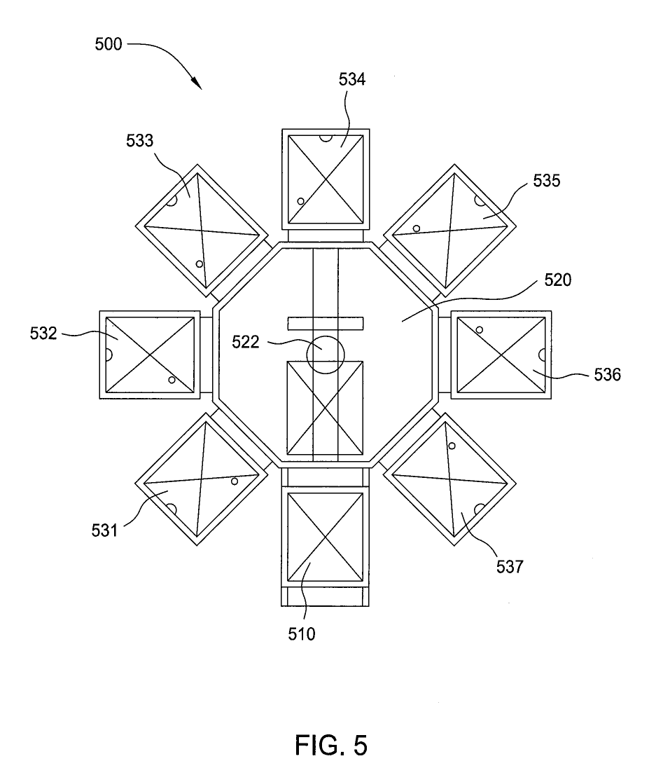

FIG. 5 is a top schematic view of one embodiment of a process system 500 having a plurality of process chambers 531-537, such as PECVD chambers chamber 400 of FIG. 4 or other suitable chambers capable of depositing silicon films. The process system 500 includes a transfer chamber 520 coupled to a load lock chamber 510 and the process chambers 531-537. The load lock chamber 510 allows substrates to be transferred between the ambient environment outside the system and vacuum environment within the transfer chamber 520 and process chambers 531-537. The load lock chamber 510 includes one or more evacuatable regions holding one or more substrate. The evacuatable regions are pumped down during input of substrates into the system 500 and are vented during output of the substrates from the system 500. The transfer chamber 520 has at least one vacuum robot 522 disposed therein that is adapted to transfer substrates between the load lock chamber 510 and the process chambers 531-537. Although there are seven process chambers shown in FIG. 5, it is contemplated that the system may have any suitable number of process chambers.

In certain embodiments of the invention, one system 500 is configured to deposit the first p-i-n junction including an intrinsic type amorphous silicon layer(s) of a multi-junction solar cell, such as the first p-i-n junction 120 of FIG. 1, FIG. 2, or FIG. 3. In one example, one of the process chambers 531-537 is configured to deposit the p-type silicon layer(s) of the first p-i-n junction while the remaining process chambers 531-537 are each configured to deposit both the intrinsic type amorphous silicon layer(s) and the n-type silicon layer(s). The intrinsic type amorphous silicon layer(s) and the n-type silicon layer(s) of the first p-i-n junction may be deposited in the same chamber with or without any passivation process in between the deposition steps. While the discussion of the process system 500 and its components references its use in forming the various elements of the first p-i-n junction, this configuration is not intended to be limiting as to the scope of the invention described herein, since the process system 500 could be adapted to form the first p-i-n junction, the second p-i-n junction (such as the second p-i-n junction 130 of FIG. 1, FIG. 2, or FIG. 3, which includes an intrinsic type microcrystalline silicon layer(s)), both the first and second p-i-n junctions, or other combinations thereof without deviating from the basic scope of the invention described herein.

In one example of a substrate processing sequence performed in the process system 500, a substrate enters the process system 500 through the load lock chamber 510, may be transferred by the vacuum robot into the dedicated process chamber configured to deposit the p-type silicon layer(s), may be transferred by the vacuum robot into one of the remaining process chambers configured to deposit both the intrinsic type silicon layer(s) and the n-type silicon layer(s), and may be transferred by the vacuum robot back to the load lock chamber 510. For example, in one example the substrate is transferred by the vacuum robot 522 into the process chamber 531, which is configured to deposit one or more p-type silicon layer(s) on the substrate, the substrate is then transferred by the vacuum robot 522 into the process chamber 534, which configured to deposit both the intrinsic type silicon layer(s) and the n-type silicon layer(s), and then the substrate is returned to the load lock chamber 510 after which the substrate can be removed from the system.

Assuming that the p-type layer is 150 Å in thickness and the deposition rate of 500 Å per minute, the period of time to deposit the p-type layer is approximately 0.3 minute. For an intrinsic layer of 2,700 Å at a deposition rate of 220 Å/minute, the time period to deposit the intrinsic layer is approximately 12.3 minutes. Assuming an n-type layer of 250 Å at a deposition rate of 500 Å per minute it will require approximately 0.5 minute to deposit the n-type layer. It can therefore be seen that if one chamber is dedicated to deposition of a p-type layer and multiple chambers are dedicated to deposition of the i-n layer, an increased throughput of substrates can be realized by increasing the number processing chambers that can produce the i-n layers in parallel. That is, a continuous series of substrates can be loaded and maneuvered by the transfer chamber 520 from a process chamber that is adapted to deposit a p-type layer, such as process chamber 531, and then transfer each of the substrates to at least one subsequent processing chamber, such as process chambers 532 through 537 to form the i-n layers. Therefore, in certain embodiments of the system to deposit the first or second p-i-n junction, the ratio of p-chambers to i/n-chambers is 1:4 or more, preferably 1:6 or more. The throughput of the system including the time to provide plasma cleaning of the process chambers may be about 10 substrates/hour or more, preferably 20 substrates/hour or more.

While the discussion of the process system 500 directs to forming the i-n layers in the same process chamber, this configuration is not intended to be limiting as to the scope of the invention described herein. For example, in one example, one of the process chambers 531-537 may be configured to deposit a p-type silicon layer(s) of the first or second p-i-n junctions, another one of the process chambers 531-537 may be configured to deposit an intrinsic silicon layer of the first or second p-i-n junctions, and another of the process chambers 531-537 may be configured to deposit the n-type silicon layer(s).

### Exemplary Cleaning Process

In a two chamber processing configuration, subsequent to deposition of the i-n layers in each of the chambers dedicated to producing the same, the process may be repeated. To preclude contamination (such as phosphorous dopant from the last n-layer) being incorporated into the intrinsic layers formed on subsequent substrates, the present inventors have proposed an improved cleaning process without impacting the solar cell device performance. The improved cleaning process may be performed in each of the chambers dedicated to producing the i-n layers in between i-n layers depositions or at some desired interval. The cleaning process may include one or more steps that are used to remove at least a portion of the previously deposited material (for example, the n-layer or p-doped layer) found on the surfaces of the components (e.g., walls 402, shadow frame 433, showerhead 410) in the processing chamber to reduce contaminations in subsequently formed layers on subsequently processed substrates 102.

In an effort to increase the substrate throughput within a processing system 500, a short cleaning process, subsequent to depositions of i-n layers in each of the chambers, is performed in each of the chambers dedicated to producing the i-n layers to remove at least a portion of the previously deposited material found on the surfaces of the components (e.g., walls 402, shadow frame 433, showerhead 410) in the processing chamber. The cleaning process is a short or partial cleaning step performed for about 5 seconds to about 45 seconds. For example, the cleaning process may be performed for about 5 seconds to about 30 seconds. In another example, the cleaning process is performed for about 5 seconds to about 20 seconds. In one embodiment, the cleaning process may utilize a high powered remote excitation source, such as that disclosed in U.S. Pat. No. 5,788,778, which is referred to above and incorporated herein by reference. The cleaning process is short enough only to remove, or substantially remove, the last or previously deposited material found on the surfaces of the components, thereby exposing the underlying material. For example, the partial cleaning process may be performed subsequent to deposition of the i-n layers in each of the chambers to remove only the n-layer or p-doped layer that was deposited on the chamber components during the n-layer deposition on the previous substrate. As the partial cleaning process is short to remove only the n-layer, the exposed underlying i-layer will serve as a seasoning layer for the next substrate coming in for i-n layer deposition, reducing and/or preventing possible contaminations to the immediately next intrinsic layer deposition due to a left over deposited n-type and/or p-type layers disposed on the chamber components. This partial cleaning process not only minimize the chances of contaminating a subsequently deposited that would have otherwise occurred due to unwanted dopants (e.g., phosphorous contained in the n-doped layer) present on the chamber components, but also extend the throughput limit (to at least 6-30 substrates in a row) of the process before a full cleaning step is necessary. By performing a short clean in between each i-n layer deposition, the throughput performance of PECVD system is significantly improved as compared to the traditional cleaning manner, which may require a full processing cycle including a cleaning process, a purging process, and a seasoning process, in between each deposition. It is contemplated that the inventive partial cleaning process is applicable to applications employing an n-i-p stack. In such a case, the partial cleaning process may be performed subsequent to deposition of the i-p layer to remove only the p-layer or n-doped layer that was previously deposited on the chamber components, exposing the intrinsic layer which serves as a seasoning layer for the next substrate coming for i-p layer deposition.

The cleaning gas used in the cleaning process may generally include, but not limited to NF₃, F₂, CF₄, SF₆, C₂F₆, CCl₄, C₂Cl₆, H₂, O₂, H₂O, a halogen and/or a halogen containing compound, or the combination thereof. Optionally, the cleaning gas may further include inert gas, such as helium or argon, to improve uniformity of dopant removal and subsequent substrate i-n layer thickness uniformity. In one example, the cleaning gases include NF₃ and Ar; He with F₂ or SF₆; O₂ and He; and O₂, He and Ar. Alternatively as opposed to using a remote plasma source, the cleaning process is accomplished by generating a plasma in the processing region 406 of the processing chamber 400 using a suitable cleaning gas, alone or in combination with inert gas, as discussed herein.

After the partial cleaning process, an optional purging process may be performed in the processing chamber to remove any undesirable residual contaminants in the processing region or on the surface of the chamber components. In one embodiment, the purging process is performed by flowing a purge gas that contains a reactive gas(es), such as hydrogen (H₂) gas, into the PECVD process chamber. In one example, the purge gas includes an inert gas, such as argon. In one configuration it is also desirable to generate a plasma during the purging process to increase the activity of the reactive gas(es) and energy of the inert gases during processing. The formation of hydrogen containing plasma during the purging steps (e.g., reference numerals 604A, 604B . . . 604N) can be effective in removing any undesirable contaminants that are bonded to, or adsorbed on, the chamber surfaces during the previous cleaning process step(s). In one example, a hydrogen plasma is used to remove the undesirable fluorine (F) or nitrogen (N) containing contaminants from the cleaning process that are bonded to, or adsorbed on, the chamber surfaces by forming a volatile HF containing vapor that is removed by the vacuum pumping system (e.g., vacuum pump 409 in FIG. 4).

By performing the partial cleaning process and optional purging process as described above in between each i-n layers deposition in each of the chambers, it is possible to run multiple substrates before the deposited film stress exceeds the film adhesion and begins to flake off the chamber components. To prevent unwanted particles from falling on the substrate, a full cleaning step followed by a seasoning step may be performed periodically or at a desired interval after processing a substrate with i-n deposition. The full cleaning step is similar to the partial cleaning process, except that the cleaning is performed longer in the chamber to substantially remove all the previously deposited material found on the surfaces of the components (e.g., walls 402, shadow frame 433, showerhead 410) in the processing chamber by an in-situ cleaning plasma or remote plasma source as described above.

After the full cleaning step, a seasoning process is performed to deposit a seasoning layer onto the surface(s) of the processing chamber components. In one embodiment, the seasoning layer is an amorphous silicon layer, which is deposited by flowing an appropriate gas such as silane through the deposition chamber and generating a plasma to deposit the layer of amorphous silicon on the surfaces of the processing chamber components. The seasoning layer acts as a shield over any residual deposited material that is disposed on the various process chamber components. The seasoning layer is generally effective in reducing and/or preventing the contamination of a deposited intrinsic layer due to a left over deposited n-type and/or p-type layers disposed on the chamber components. In one example, the seasoning layer is deposited by providing a gas mixture of hydrogen gas to silane gas in a ratio of about 1:20 or less at a chamber pressure between about 0.1 Torr and about 20 Torr. Silane gas may be provided at a flow rate between about 0.5 sccm/L and about 7 sccm/L, and the hydrogen gas may be provided at a flow rate between about 5 sccm/L and about 60 sccm/L. An RF power of between 15 milliWatts/cm² and about 250 milliWatts/cm² may be provided to the showerhead. In one example, the seasoning layer thickness is greater than about 200 Å. In another example, the seasoning layer thickness is greater than about 500 Å. In yet another example, the seasoning layer thickness is between about 500 Å and about 1500 Å. Although not discussed here, it is contemplated that the seasoning layer may be a microcrystalline silicon layer when processing the second p-i-n junction 130. However, since microcrystalline silicon has different degrees of crystallinity compared to amorphous intrinsic layer, it may require a longer range of actual clean time to remove the dopant layer, depending on the density and power. If the power is higher, it may take for example 5-80 seconds to remove the last or previously deposited material found on the surfaces of the components.

In general, the seasoning process is performed without a substrate being disposed in the processing region of the processing chamber. However, in some cases during one or more of the seasoning process steps a dummy substrate, or a non-usable substrate, is positioned on the substrate support to reduce future substrate contamination and device yield problems. In one example, a dummy substrate is disposed on the substrate supporting surface to prevent deposition of the seasoning layer on the substrate supporting surface.

It has been found that a full cleaning process and seasoning process performing at regular or desired intervals in conjunction with partial cleaning process in between the deposition steps performed in each of the processing chambers in a cluster tool (e.g., processing system 500 in FIG. 5) significantly improves throughput performance of a substrate processing sequence that is used to form one or more layers within the first p-i-n junction 120 and/or second p-i-n junction 130 while maintaining a good quality of film deposition.

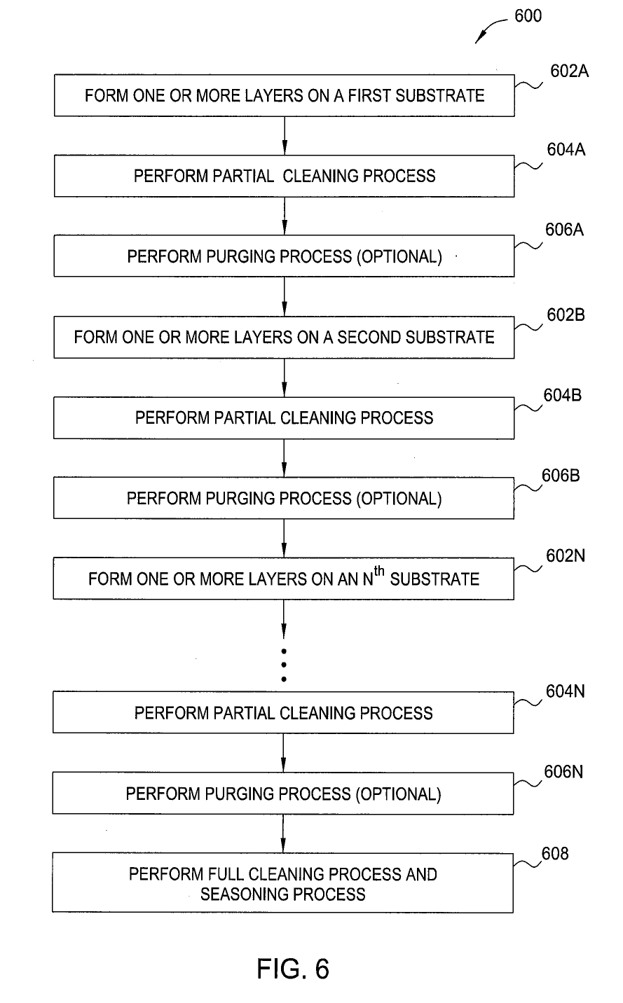

FIG. 6 illustrates one embodiment of a processing sequence 600 performed in a processing chamber in which a series of deposition process steps (e.g., reference numerals 602A, 602B . . . 602N) are performed on multiple substrates with a partial cleaning process (e.g., reference numerals 604A, 604B . . . 604N) being performed after each of the deposition process step prior to a full cleaning process and a seasoning process is performed. As shown in FIG. 6, the processing sequence 600 includes forming one or more layers on a substrate and then performing a partial cleaning process in the processing chamber sequentially N number of times, where N is a number of substrates processed before cracking and flaking off of contaminating deposits from the chamber components. An optional purging process (e.g., reference numerals 606A, 606B . . . 606N) may be performed after partial cleaning process to remove undesirable fluorine (F) or nitrogen (N) containing contaminants from the cleaning process as discussed above. A full cleaning process followed by a seasoning process (e.g., reference numerals 608) is performed at regular or desired intervals to enhance the quality of the film deposition. In general, each of the deposition process step 602A-602N includes forming an intrinsic type layer and then forming a dopant containing layer, such as an n-type or p-type layer, on a substrate. The partial cleaning process 604A-604N, the optional purging process 606A-606N, and the full cleaning process and the seasoning process 608 are similar to those as discussed above.

While the foregoing is directed to embodiments of the present invention, other and further embodiments of the invention may be devised without departing from the basic scope thereof, and the scope thereof is determined by the claims that follow. For example, the process chamber if FIG. 4 has been shown in a horizontal position. It is understood that in other embodiments of the invention the process chamber may be in any non-horizontal position, such as vertical. For example, embodiments of the invention have been described in reference to the multi-process chamber cluster tool in FIG. 5. It is understood that embodiments of the invention may also be practiced in on in-line systems and hybrid in-line/cluster systems. For example, embodiments of the invention have been described in reference to a first system configured to form a first p-i-n junction and a second p-i-n junction. It is understood that in other embodiments of the invention, the first p-i-n junction and a second p-i-n junction may be formed in a single system. For example, embodiments of the invention have been described in reference to a process chamber adapted to deposit both an intrinsic type layer and an n-type (or p-type) layer. It is understood that in other embodiments of the invention, separate chambers may be adapted to deposit the intrinsic type layer and the n-type layer (or p-type). It is understood that in other embodiments of the invention, a process chamber may be adapted to deposit both a p-type layer and an intrinsic type layer.

1. A method of processing a plurality of thin film solar cell substrates, comprising:
depositing sequentially a first undoped layer and a first doped layer over a surface of a first substrate and a chamber component in a single processing chamber;
removing the substrate having the doped and undoped layers from the processing chamber;
removing the first doped layer deposited on the chamber component to expose underlying first undoped layer which serves as a seasoning layer for a second substrate to be processed in the processing chamber; and
depositing sequentially a second undoped layer and a second doped layer on the second substrate in the processing chamber.

2. The method of claim 1, wherein the removing the first doped layer comprises cleaning the processing chamber using an in-situ or a remote plasma source with a cleaning gas.

3. The method of claim 2, wherein the cleaning gas is selected from the group consisting of NF₃, NF₃ and N₂, NF₃ and argon, NF₃ and O₂, a dilute F₂, CF₄, C₂F₆, C₃F₈, SF₆, and Cl₂, hydrogen-containing gas, ammonium, helium, argon, and combinations thereof.

4. The method of claim 1, wherein the first undoped layer is amorphous silicon or microcrystalline silicon.

5. The method of claim 2, wherein the cleaning is performed between about 5 and about 80 seconds.

6. The method of claim 1, further comprising:
performing a purging process after removing the first doped layer by flowing an inert gas into the processing chamber.

7. A method of processing a plurality of thin film solar cell substrates, comprising:
depositing a first intrinsic type layer on a surface of a first substrate and on a chamber component in the first processing chamber;
depositing a first doped layer over the first intrinsic type layer formed on the first substrate and on the chamber component in the first processing chamber;
removing the first substrate having the first doped layer and the first intrinsic type layer from the first processing chamber; and
performing a first partial cleaning process in the first processing chamber, wherein the first partial cleaning process removes substantially the first doped layer that was deposited on the chamber component during the first doped layer deposition while leaving the first intrinsic type layer of the chamber component.

8. The method of claim 7, further comprising:
after performing the first partial cleaning process, placing a second substrate into the first processing chamber;
depositing a second intrinsic type layer on a surface of a second substrate and on the chamber component in the first processing chamber;
depositing a second doped layer over the second intrinsic type layer formed on the second substrate and on the chamber component in the first processing chamber;
removing the second substrate having the second doped layer and the second intrinsic type layer from the first processing chamber; and
performing a second partial cleaning process in the first processing chamber, wherein the second partial cleaning process removes substantially the second doped layer that was deposited on the chamber component while leaving the second intrinsic type layer of the chamber component.

9. The method of claim 8, wherein the first and the second partial cleaning processes comprise cleaning a processing region of the first processing chamber using an in-situ or a remote plasma source with a cleaning gas.

10. The method of claim 9, wherein the cleaning gas is selected from the group consisting of NF₃, NF₃ and N₂, NF₃ and argon, NF₃ and O₂, a dilute F₂, CF₄, C₂F₆, C₃F₈, SF₆, and Cl₂, hydrogen-containing gas, ammonium, helium, argon, and combinations thereof.

11. The method of claim 8, further comprising:
performing a full cleaning process at desired intervals to expose the surfaces of the chamber component; and
performing a seasoning process to deposit a seasoning layer onto the surfaces of the chamber components.

12. The method of claim 11, wherein the first and second intrinsic type layers are amorphous silicon or microcrystalline silicon.

13. The method of claim 12, wherein the first and the second partial cleaning process are performed between about 5 seconds to about 80 seconds.

14. The method of claim 8, further comprising:
performing a purging process after the first and second partial cleaning process by flowing an inert gas into the processing chamber.

15. A method of processing a plurality of thin film solar cell substrates, comprising:
depositing sequentially a first intrinsic type layer and a first doped layer on a surface of a first substrate and on a first chamber component in a first processing chamber, wherein the first chamber component and the first substrate are disposed in a processing region of the first processing chamber when the first intrinsic type layer and the first doped layer are deposited on the first substrate;
removing the substrate having the first intrinsic type layer and the first doped layer from the first processing chamber;
performing a partial cleaning process in the first processing chamber to remove the first doped layer that was deposited over the first intrinsic type layer on the first chamber component during the first doped layer deposition, thereby exposing underlying first intrinsic type layer which serves as a seasoning layer for a second substrate to be processed in the first processing chamber; and
depositing sequentially a second intrinsic type layer and a second doped layer on a surface of the second substrate and on the first chamber component in the first processing chamber, wherein the first chamber component and the second substrate are disposed in the processing region of the first processing chamber when the second intrinsic type layer and the second doped layer are deposited on the second substrate.

16. The method of claim 15, wherein the partial cleaning process comprises cleaning the processing region of the first processing chamber using an in-situ or a remote plasma source with a cleaning gas.

17. The method of claim 16, wherein the cleaning gas is selected from the group consisting of NF₃, NF₃ and N₂, NF₃ and argon, NF₃ and O₂, a dilute F₂, CF₄, C₂F₆, C₃F₈, SF₆, and Cl₂, hydrogen-containing gas, ammonium, helium, argon, and combinations thereof.

18. The method of claim 15, further comprises depositing an underlying doped layer on the first substrate in a second processing chamber before depositing the first intrinsic type layer on the first substrate, wherein the underlying doped layer comprises dopant atoms that are not the same as dopant atoms disposed in the first doped layer.

19. The method of claim 18, wherein the underlying doped layer comprises a p-type silicon containing layer or an n-type silicon containing layer.

20. The method of claim 15, further comprising:
performing a full cleaning process at desired intervals to expose the surfaces of the chamber component; and
performing a seasoning process to deposit a seasoning layer onto the surfaces of the chamber components, wherein the seasoning layer is amorphous silicon or microcrystalline silicon.
